(19) United States
(12) Patent Application Publication
(10) Pub. No.: US 2022/0406711 A1
(43) Pub. Date: Dec. 22, 2022

(54) SEMICONDUCTOR DEVICE AND SEMICONDUCTOR SYSTEM

(71) Applicant: FLOSFIA INC., Kyoto (JP)

(72) Inventors: Shogo MIZUMOTO, Kyoto (JP); Hideaki YANAGIDA, Kyoto (JP)

(21) Appl. No.: 17/894,662

(22) Filed: Aug. 24, 2022

Related U.S. Application Data
(63) Continuation-in-part of application No. PCT/JP2021/006856, filed on Feb. 24, 2021.

(30) Foreign Application Priority Data
Feb. 25, 2020 (JP) 2020-029508

(51) Int. Cl. H01L 23/525; H01L 23/522; H01L 23/34

(52) U.S. Cl. CPC H01L 23/5256; H01L 23/5226; H01L 23/34

(57) ABSTRACT

Provided is a semiconductor device, including: a first electrode layer including a first wiring member and a second electrode layer including a second wiring member, the first electrode layer and the second electrode layer being disposed to face each other; a semiconductor element disposed in a gap between the first and second electrode layers, and electrically connected to the first and second electrode layers; and a via disposed in the gap between the first and second electrode layers, electrically connected to the first and second electrode layers, and configured to detect a state of the semiconductor element by being fractured at a predetermined temperature and losing electric connection.

### CROSS REFERENCE TO RELATED APPLICATION

This application is a continuation-in-part application of International Patent Application No. PCT/JP2021/006856 (Filed on Feb. 24, 2021), which claims the benefit of priority from Japanese Patent Application No. 2020-029508 (filed on Feb. 25, 2020).

The entire contents of the above applications, which the present application is based on, are incorporated herein by reference.

### 1. FIELD OF THE INVENTION

The present disclosure relates to a semiconductor device and a semiconductor system each mounted with a semiconductor element, and particularly to a semiconductor device and a semiconductor system in which a protection circuit against heat generation is easily configurable.

### 2. DESCRIPTION OF THE RELATED ART

A thyristor, an insulated gate bipolar transistor (IGBT), or a power semiconductor such as a power transistor and a power MOSFET is used in a wide application range. The power semiconductor may include a power semiconductor switch that switches a current exceeding 10 A and/or a voltage exceeding 500 V.

Development of the power semiconductor is directed to a device high in switching. It is possible to reduce a switching time by optimizing a silicon (Si) device, and using a wide band gap semiconductor material, for example, silicon carbide (SiC), a gallium nitride (GaN), or gallium oxide (Ga₂O₃).

### SUMMARY OF THE INVENTION

According to an example of the present disclosure, there is provided a semiconductor device, including: a first electrode layer including a first wiring member and a second electrode layer including a second wiring member, the first electrode layer and the second electrode layer being disposed to face each other; a semiconductor element disposed in a gap between the first and second electrode layers, and electrically connected to the first and second electrode layers; and a via disposed in the gap between the first and second electrode layers, electrically connected to the first and second electrode layers, and configured to detect a state of the semiconductor element by being fractured at a predetermined temperature and losing electric connection.

According to an example of the present disclosure, there is provided a semiconductor system, including: a first electrode layer including a first wiring member and second electrode layer including a second wiring member, the first electrode layer and the second electrode layer being disposed to face each other; a semiconductor element disposed in a gap between the first and second electrode layers, and electrically connected to the first and second electrode layers; a via disposed in the gap between the first and second electrode layers, electrically connected to the first and second electrode layers, and configured to lose electric connection by being fractured at a predetermined temperature; and a monitoring control unit configured to generate a control signal based on an electric signal of the via.

According to an example of the present disclosure, there is provided a semiconductor device including: a first electrically conductive layer including a first wiring member and a second electrically conductive layer including a second wiring member, the first electrically conductive layer and the second electrically conductive layer being disposed to face each other; a semiconductor element disposed in a gap between the first and the second electrically conductive layer and electrically connected to the first and second electrically conductive layers; and an electrically conductive member that is electrically connected to the semiconductor element, the first electrically conductive layer and/or the second electrically conductive layer, the electrically conductive member being configured to be fractured at a predetermined temperature.

Thus, in a semiconductor device of the present disclosure and/or a semiconductor system of the present disclosure, it is possible to detect an overload state of the semiconductor element, and it is possible to suppress adverse effect on the control target by, for example, stopping current supply to the semiconductor element.

### BRIEF DESCRIPTION OF THE DRAWINGS

FIG. 1 is a cross-sectional view of a semiconductor device according to an embodiment of the present disclosure.

FIG. 2 is a schematic configuration diagram of a semiconductor system that includes a circuit configuration of the semiconductor device according to the embodiment of the present disclosure.

### DETAILED DESCRIPTION

Embodiments of the present disclosure will be described below with reference to the accompanying drawings. In the following description, the same parts and components are designated by the same reference numerals. The present embodiment includes, for example, the following disclosures.

### [Structure 1]

A semiconductor device, including: a first electrode layer including a first wiring member and a second electrode layer including a second wiring member, the first electrode layer and the second electrode layer being disposed to face each other; a semiconductor element disposed in a gap between the first and second electrode layers, and electrically connected to the first and second electrode layers; and a via disposed in the gap between the first and second electrode layers, electrically connected to the first and second electrode layers, and configured to detect a state of the semiconductor element by being fractured at a predetermined temperature and losing electric connection.

### [Structure 2]

The semiconductor device according to [Structure 1], wherein the via is configured to be fractured by tensile stress generated by thermal expansion difference with a material having a high thermal expansion coefficient.

### [Structure 3]

The semiconductor device according to [Structure 1], wherein the via is configured to be fractured by melting.

### [Structure 4]

The semiconductor device according to [Structure 1], wherein a circuit to supply power to the semiconductor element is different from a circuit to supply power to the via.

### [Structure 5]

The semiconductor device according to [Structure 1], wherein the semiconductor element includes a power semiconductor.

### [Structure 6]

A semiconductor system, including: a first electrode layer including a first wiring member and second electrode layer including a second wiring member, the first electrode layer and the second electrode layer being disposed to face each other; a semiconductor element disposed in a gap between the first and second electrode layers, and electrically connected to the first and second electrode layers; a via disposed in the gap between the first and second electrode layers, electrically connected to the first and second electrode layers, and configured to lose electric connection by being fractured at a predetermined temperature; and a monitoring control unit configured to generate a control signal based on an electric signal of the via.

### [Structure 7]

The semiconductor system according to [Structure 6], wherein the via is configured to be fractured by tensile stress generated by thermal expansion difference with a material having a high thermal expansion coefficient.

### [Structure 8]

The semiconductor system according to [Structure 6], wherein the via is configured to be fractured by melting.

### [Structure 9]

The semiconductor system according to [Structure 6], wherein a circuit to supply power to the semiconductor element is different from a circuit to supply power to the via.

### [Structure 10]

The semiconductor system according to [Structure 6], wherein the semiconductor element includes a power semiconductor.

### [Structure 11]

A semiconductor device including: a first electrically conductive layer including a first wiring member and a second electrically conductive layer including a second wiring member, the first electrically conductive layer and the second electrically conductive layer being disposed to face each other; a semiconductor element disposed in a gap between the first and the second electrically conductive layer and electrically connected to the first and second electrically conductive layers; and an electrically conductive member that is electrically connected to the semiconductor element, the first electrically conductive layer and/or the second electrically conductive layer, the electrically conductive member being configured to be fractured at a predetermined temperature.

A semiconductor device according to an embodiment of the present disclosure is described below with reference to drawings.

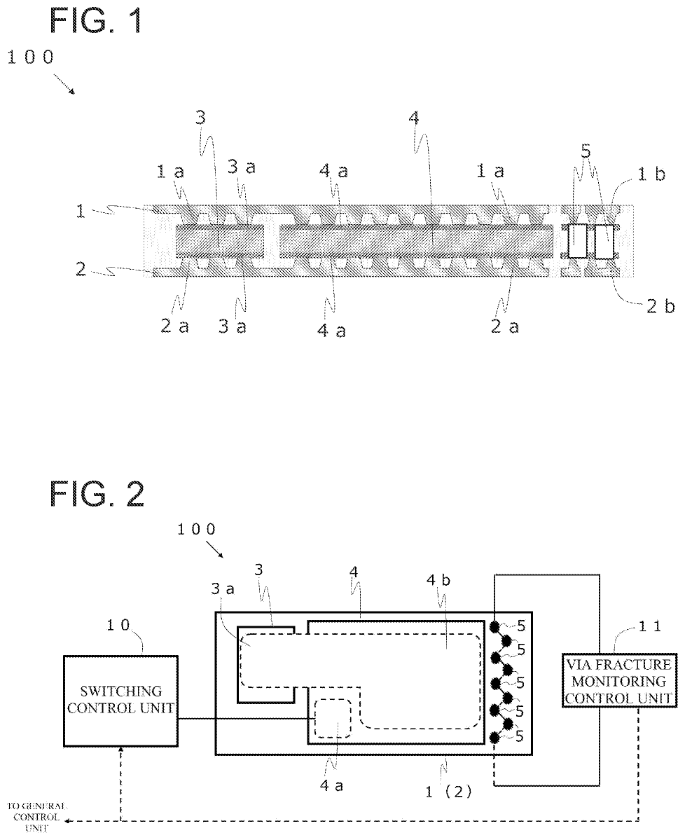

FIG. 1 is a cross-sectional view illustrating the semiconductor device according to the embodiment of the present disclosure, and FIG. 2 is a schematic configuration diagram of a semiconductor system including an electric circuit in a case where FIG. 1 is viewed from above. As illustrated in the drawings, in a semiconductor device 100, semiconductor elements 3 and 4 are sandwiched between first electrode layer (a first electrically conductive layer) 1 and a second electrode layer (a second electrically conductive layer) 2 that are disposed in parallel (to face each other). In other word, as apparent from FIG. 1, the semiconductor elements 3 and 4 are disposed in a gap between the first electrode layer and the second electrode layer. The first electrode layer 1 and the second electrode layer 2 are connected to electrode surfaces 3a and 4a provided on both upper and lower surfaces of the semiconductor elements 3 and 4 through a plurality of convex contacts 1a and 2a. Accordingly, the electrode layers 1 and 2 are electrically connected to the semiconductor elements 3 and 4, and desired operation required as the semiconductor device 100 is performed by switching operation of the semiconductor elements 3 and 4. Also, not shown in FIG. 1, the first electrode layer (the first electrically conductive layer) includes a first wiring member and the second electrode layer (the second electrically conductive layer) includes a second wiring member. The first and second wiring member may have a patterned structure.

Note that the semiconductor element 3 is a diode such as a Schottky barrier diode (SBD), and the semiconductor element 4 may be, for example, an insulated gate bipolar transistor (IGBT), a bipolar transistor, or an MOSFET (Metal-Oxide-Semiconductor Field effect transistor). The semiconductor element 3 and the semiconductor element 4 are appropriately selected in consideration of the circuit configuration based on an application target and a specification of the semiconductor device 100.

The first electrode layer 1 and the second electrode layer 2 includes a gap corresponding to thicknesses of the semiconductor elements 3 and 4 at a position adjacent to the semiconductor elements 3 and 4, and vias 5 are disposed in the gap. Both upper and lower ends of each of the vias 5 are connected to contacts 1b of the first electrode layer 1 and contacts 2b of the second electrode layer 2. The contacts 1b and 2b connected to the vias 5 belong to a circuit different from a circuit of the contacts 1a and 2a connected to the semiconductor elements 3 and 4, and a control current flowing through the contacts 1b and 2b is different from a control current flowing through the contacts 1a and 2a. According to the present disclosure, the semiconductor device includes an electrically conductive member that is electrically connected to the semiconductor element 3, the semiconductor element 4, first electrically conductive layer, and/or the second electrically conductive layer; the electrically conductive member is configured to be fractured at a predetermined temperature. FIG. 1 and FIG. 2 illustrates an example when the electrically conductive member is a via and arranged in a gap between the first electrically conductive layer (the first electrode layer) and the second electrically conductive layer (the second electrode layer), but the present disclosure is not limited to this configuration. The electrically member may be arranged in the first or second wiring member or may be arranged, as a via, between the first electrically conductive layer and the second electrically conductive layer.

As illustrated in FIG. 2, the plurality of vias 5 are disposed in series on the same circuit so as to electrically connect between the contacts 1b and 2b, and such that vias through which the current flows from the contact 1b to the contact 2b and the vias through which the current flows from the contact 2b to the contact 1b are alternately arranged. The number of vias 5 is not limited to the present embodiment as a matter of course, and it is sufficient to provide one or more vias 5. Specific functions of the vias 5 are described below.

Although not illustrated, a heat dissipation mechanism may be connected to the first electrode layer 1 and the second electrode layer 2. The heat dissipation mechanism may be a mechanism having a wide surface area for heat dissipation, for example, a heat dissipation fin, or may be a mechanism that circulates air or water to perform heat exchange.

In the semiconductor device 100 configured as described above according to the present embodiment, currents are applied to the semiconductor elements 3 and 4 based on signals from a switching control unit 10, and switching signals are serially or individually supplied to the semiconductor elements 3 and 4. In a case where the semiconductor element 3 is the SBD and the semiconductor element 4 is the IGBT, a voltage signal is input to gate electrodes 4a in the IGBT 4 as illustrated in FIG. 2. In response thereto, switching operation is performed by the current flowing through an emitter 4b of the IGBT 4 and a current flowing through an anode 3a of the SBD 3, and an unillustrated control target is controlled. According to the present disclosure, the control unit may be configured with a processor (e.g. a CPU (Central Processing Unit) or a MPU (Micro-Processing Unit)).

On the other hand, a circuit in which the plurality of vias 5 are connected in series is a circuit different from the circuit of the semiconductor elements 3 and 4, and is monitored by a via fracture monitoring control unit 11. A control signal from the via fracture monitoring control unit 11 is output to the switching control unit 10, and is also supplied to an unillustrated general control unit. The general control unit is used to control a host system of the semiconductor device 100, for example, an electric vehicle and an apparatus in a high-speed railway each mounted with the semiconductor device 100.

In the semiconductor device 100 according to the present embodiment, requests for downsizing and high performance of the semiconductor device are increased, and countermeasures against thermal influence is becoming necessary, with the rise of a power semiconductor element. For example, in a case where the semiconductor elements 3 and 4 are disposed in a closed space between the electrode layers 1 and 2, or in a case where the semiconductor elements 3 and 4 receive thermal influence from the other surrounding elements, there is a risk that thermal limit of the semiconductor device 100 is exceeded due to exposure of the whole of the semiconductor device 100 to high temperature, and the semiconductor elements 3 and 4 may run out of control or may be functionally stopped. To release the semiconductor device 100 from a thermal load before reaching such a situation, the vias 5 that are fractured under a predetermined thermal condition are disposed inside the semiconductor device 100, and fracture of the vias 5 and loss of the electric connection are determined by detecting the current.

In the present embodiment, the plurality of vias 5 are disposed at appropriate positions in the electrode layers 1 and 2, for example, near the semiconductor element 4, which makes it possible to reproduce, in the vias 5, an environment equivalent to a thermal environment in or near the semiconductor element 4. When such vias 5 are disposed at the appropriate positions in the electrode layers 1 and 2 and are electrically connected in series, the current does not flow through the circuit even in a case where any one of the vias is fractured. Therefore, the via fracture monitoring control unit 11 determines limit of the thermal load. Further, the via fracture monitoring control unit 11 issues an instruction to inhibit any further operation of the semiconductor elements 3 and 4, to the switching control unit 10, and instructs the switching control unit 10 to stop control of the ON/OFF signals to the unillustrated switching element by applying a voltage to the gate electrodes 4a, or to supply only the OFF signal.

On the other hand, the via fracture monitoring control unit 11 outputs a signal also to the general control unit, and the general control unit accordingly generates an instruction controlling the whole of the system, for example, generates a backup signal (for example, switching of control to another semiconductor device not having thermal problem), along with operation stoppage of the semiconductor device 100. Note that the semiconductor system according to the present embodiment includes the semiconductor device 100 according to the present embodiment and at least one of the switching control unit 10, the via fracture monitoring control unit 11, the unillustrated control target, and the like.

Some methods of fracturing the vias 5 at the predetermined temperature are considered.

For example, an epoxy resin connecting the first and second electrode layers 1 and 2 is disposed, through holes are bored in the epoxy resin, and the vias 5 are provided inside the through holes. In general, the vias are each preferably made of copper. A phenomenon in which, when the semiconductor device 100 receives thermal influence, excess tensile stress acts on copper due to difference in thermal expansion coefficient between the epoxy resin and copper, thereby fracturing the via is used. The epoxy resin is a material generally used for an electrode layer. Therefore, integral formation of the through holes with the electrode layers 1 and 2 and providing of the vias in the through holes are relatively easily performable.

As another method, the vias 5 may be made of a material or a structure fractured at a specific melting point. For example, the vias are made of low-melting point solder, or vias are formed to be thin in a part of a cross-section. This makes it possible to easily cause fracture of the vias by melting under an environment hard in thermal influence.

In any of the above-described cases, the object is achieved by appropriately designing the vias 5 after an allowable temperature necessary to fracture the vias 5 is previously determined.

In a case where a power semiconductor is used as the semiconductor element, thermal problem may be particularly remarkable. Therefore, the effects by the present disclosure are greatly expected.

Although the embodiment of the present disclosure is described above, the present disclosure is not limited thereto, and is variously modified and implemented. For example, the structure in which the electrode layers are connected to both surfaces of the semiconductor elements as illustrated in the present embodiment is unnecessary, and the semiconductor element may be mounted only on single surfaces of the electrode layers. In this case, a mode in which the semiconductor device is housed in a closed space in a package form is considered. Further, the semiconductor element to be mounted is any semiconductor element, and inclusion of the power semiconductor is not essential. In other words, the type, the number, the size, the allowable current value, and the like of the semiconductor element are not limited as long as resolution of the thermal issue of the semiconductor device that is the object of the present disclosure is achieved.

The embodiments of the present invention are exemplified in all respects, and the scope of the present invention includes all modifications within the meaning and scope equivalent to the scope of claims.

### REFERENCE SIGNS LIST

1, 2 Electrode layer
3, 4 Semiconductor element
5 Via
10 Switching control unit
11 Via fracture monitoring control unit
100 Semiconductor device

What is claimed is:

1. A semiconductor device, comprising:
a first electrode layer including a first wiring member and a second electrode layer including a second wiring member,
the first electrode layer and the second electrode layer being disposed to face each other;
a semiconductor element disposed in a gap between the first and second electrode layers, and electrically connected to the first and second electrode layers; and
a via disposed in the gap between the first and second electrode layers, electrically connected to the first and second electrode layers, and configured to detect a state of the semiconductor element by being fractured at a predetermined temperature and losing electric connection.

2. The semiconductor device according to claim 1, wherein the via is configured to be fractured by tensile stress generated by thermal expansion difference with a material having a high thermal expansion coefficient.

3. The semiconductor device according to claim 1, wherein the via is configured to be fractured by melting.

4. The semiconductor device according to claim 1, wherein a circuit to supply power to the semiconductor element is different from a circuit to supply power to the via.

5. The semiconductor device according to claim 1, wherein the semiconductor element includes a power semiconductor.

6. A semiconductor system, comprising:
a first electrode layer including a first wiring member and second electrode layer including a second wiring member,
the first electrode layer and the second electrode layer being disposed to face each other;
a semiconductor element disposed in a gap between the first and second electrode layers, and electrically connected to the first and second electrode layers;
a via disposed in the gap between the first and second electrode layers, electrically connected to the first and second electrode layers, and configured to lose electric connection by being fractured at a predetermined temperature; and
a monitoring control unit configured to generate a control signal based on an electric signal of the via.

7. The semiconductor system according to claim 6, wherein the via is configured to be fractured by tensile stress generated by thermal expansion difference with a material having a high thermal expansion coefficient.

8. The semiconductor system according to claim 6, wherein the via is configured to be fractured by melting.

9. The semiconductor system according to claim 6, wherein a circuit to supply power to the semiconductor element is different from a circuit to supply power to the via.

10. The semiconductor system according to claim 6, wherein the semiconductor element includes a power semiconductor.

11. A semiconductor device comprising:
a first electrically conductive layer including a first wiring member and a second electrically conductive layer including a second wiring member,
the first electrically conductive layer and the second electrically conductive layer being disposed to face each other;
a semiconductor element disposed in a gap between the first and the second electrically conductive layer and electrically connected to the first and second electrically conductive layers; and
an electrically conductive member that is electrically connected to the semiconductor element, the first electrically conductive layer and/or the second electrically conductive layer,
the electrically conductive member being configured to be fractured at a predetermined temperature.
